(19) United States
(12) Patent Application Publication
(10) Pub. No.: US 2007/0058343 A1
(43) Pub. Date: Mar. 15, 2007

(54) HEAT PIPE TYPE HEAT DISSIPATION DEVICE

(75) Inventors: Gen-Ping Deng, Shenzhen (CN); Yi-Qiang Wu, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: FOXCONN TECHNOLOGY CO., LTD., Tu-Cheng,Taipei Hsien (TW)

(21) Appl. No.: 11/308,918

(22) Filed: May 25, 2006

(30) Foreign Application Priority Data
Sep. 14, 2005 (CN) 200510037333.2

(51) Int. Cl. H05K 7/20

(52) U.S. Cl. 361/695; 165/80.3

(57) ABSTRACT

A heat pipe type heat dissipation device for an electronic component comprises a base, a heat dissipation member and two U-shaped heat pipes connecting the heat dissipation member with the base. The heat pipes each have an evaporation section connected to the base and two condensation sections perpendicularly extending from opposite ends of the evaporation section. The heat dissipation member comprises a cylindrical heat transfer wall constructed around and separated from an axis thereof perpendicular to the base, which defines a through opening. A plurality of fins extends in the through opening from an inner face of the heat transfer wall toward the axis so as to define a plurality of air channels between the fins which extend from one open end of the heat transfer wall to the other.

### FIELD OF THE INVENTION

The present invention generally relates to heat dissipation devices, and more particularly to a heat pipe type heat dissipation device for removing heat from a heat-generating electronic component.

### DESCRIPTION OF RELATED ART

The continuing and fast development of the electronic industry has resulted in a remarkable increase in the heat generated by electronic components. If this heat cannot be removed away in time from the electronic components, damage to the electronic components will be inevitable. On the other hand, the drive towards greater miniaturization is a prevalent tendency in the development of electronic equipment and this tendency further increases the difficulty of dissipating heat from electronic components.

A heat sink has become an essential apparatus for preventing electronic components from overheating, therefore ensuring normal operation thereof. A conventional heat sink comprises a plate-shaped base for contacting with an electronic component in a manner so as to absorb heat for dispersal, and a plurality of fins provided on a top face of the base for dissipating the heat transferred from the base to the fins only by metal conduction. A fan is generally mounted to a top of the heat sink to provide airflow through the heat sink so as to strengthen heat dissipation. In such heat sinks, flat plate base creates air deflection and collision between the base and the fan, which depresses the efficiency of the fan and further decreases the performance of the whole heat dissipation device.

U.S. Pat. No. 6,671,172 discloses a star-shaped heat dissipation device. In this disclosure, the heat dissipation device comprises a core and a plurality of fins radially extending from the circumferential surface of the core. A fan is mounted to the top of the core. When in use, a bottom face of the core contacts with an electronic component to absorb heat and conduct it upwards along the core. The heat is then transferred to the fins for dissipation with the aid of the fan. A distinct disadvantage exists in this heat dissipation device, shown as follows. The core has its hottest bottom portion adjacent to the electronic component, and there is a temperature drop from the bottom portion to the top portion and from the inside to the outer portions of the heat dissipation device, especially towards the tips of the fins. The fan has increasing air flux and speed from the center towards the periphery thereof. That is, the hottest portion of the heat dissipation device is positioned corresponding to the position with the lowest air flux. Obviously this configuration has room for improvement. The airflow from the fan flows away from the core when traveling downwards, thus reducing the heat dissipation of the hottest portions. Also, such a heat sink operates only by solid metal thermal conduction, and therefore can not cope with highly heat generating electronic components.

In recent years, phase change type products such as heat pipes have been widely applied in the field of heat dissipation due to their excellent heat transfer capability. A heat pipe commonly comprises a hollow, sealed pipe defining an elongated chamber in which a working liquid such as water, alcohol, etc, is contained. Wick capillaries are laid along an inner face of pipe to carry the working liquid from one end of the pipe to the other. The heat pipe functions by a continuous cycle of work liquid evaporation at one end and condensation at another, thus carrying heat from one end, commonly called the evaporation section, to the other, commonly called the condensation section.

Usually, heat pipes are used in combination with other elements, such as fins, spreaders, etc. to assembly a heat pipe type heat dissipation device. Heat pipes can be formed into many shapes including U-bend and V-shape.

What is needed, therefore, is a high performance heat pipe type heat dissipation device for efficiently removing heat from a heat-generating electronic device, whilst maximizing the use of any fans mounted therein.

### SUMMARY OF THE INVENTION

A heat pipe type heat dissipation device comprises a base, at least a heat pipe connected to the base, and a heat dissipation member connected to the heat pipe. The heat dissipation member includes a heat transfer wall constructed around and separated from an axis thereof so as to define a through opening into which a plurality of fins extend from an inner face of the heat transferring wall toward the axis, therefore defining a plurality of air channels in the opening. A fan is mounted on a top of the heat dissipation member for providing an airflow through the air channels. The heat dissipation member is consisted of at least two heat dissipation sub-members combined together. The heat pipe has a condensation section sandwiched between the at least two heat dissipation sub-members

Other advantages and novel features of the invention will be readily apparent from the following detailed descriptions, taken in conjunction with the accompanying drawings; in which:

### BRIEF DESCRIPTION OF THE DRAWINGS

Many aspects of the apparatus of the present invention can be better understood with reference to the following drawings. The components in the drawings are not necessarily drawn to scale, the emphasis instead being placed upon clearly illustrating the principles of the present apparatus and method. Moreover, in the drawings, like reference numerals designate corresponding parts throughout the several views.

FIG. 1 is an isomeric view of the heat dissipation device in accordance with a preferred embodiment of the present invention;

FIG. 2 is an exploded view of FIG. 1 without a fan thereof;

FIG. 3 is an exploded view of the heat dissipation device in accordance with a second embodiment of the present invention;

FIG. 4 is an exploded view of the heat dissipation device in accordance with a third embodiment of the present invention; and,

FIG. 5 is an exploded view of the heat dissipation device in accordance with a fourth embodiment of the present invention.

### DETAILED DESCRIPTION OF THE INVENTION

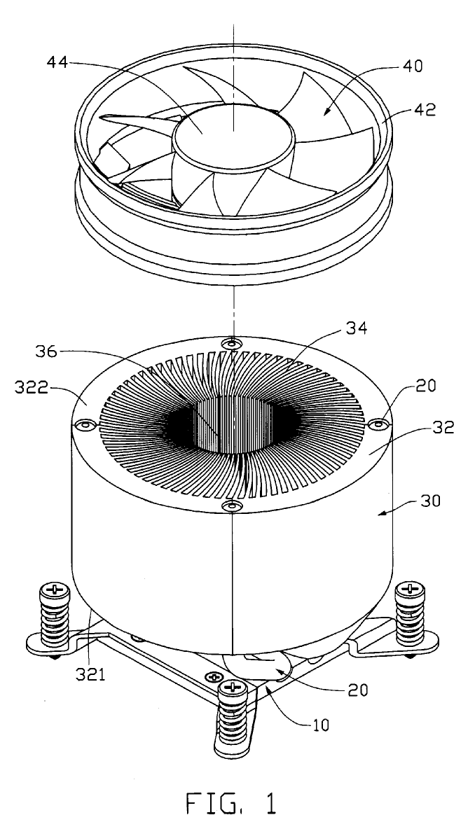

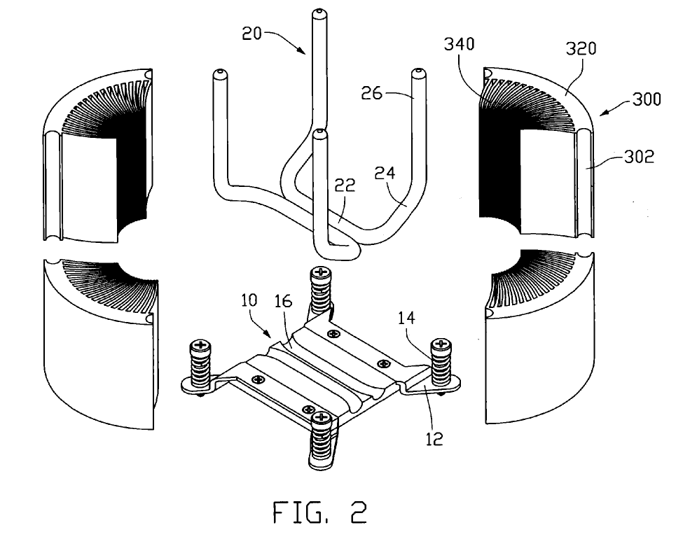

Referring to FIGS. 1 and 2, a heat pipe type heat dissipation device in accordance with a preferred embodiment of the present invention is used for dissipating heat from an electronic component (not shown), and comprises a flat plate-shaped base 10, two heat pipes 20 connected to the base 10, a heat dissipation member 30 connected to the heat pipes 20, and a fan 40 to be mounted on a top of the heat dissipation member 30.

Referring to FIG. 2, the base 10 is a rectangular flat plate having a bottom face (not shown) for contacting with the electronic component to draw heat therefrom and a top face (not labeled) opposite to the bottom face. The base 10 defines two parallel grooves 16 on the top face thereof. Four fixing arms 12 are provided at the four corners of the base 10, and project outwards. Each fixing arm 12 defines a fixing hole (not shown), and four screws 14 with springs (not labeled) are received in the fixing holes with one screw 14 for each fixing hole for mounting the heat dissipation device to a printed circuit board (not shown) on which the electronic component is mounted.

The heat pipes 20 each are shaped in a U-bend configuration, including an evaporation section 22 and two condensation sections 26 bent from opposite ends of the evaporation section 22. A transitional section 24 connects the evaporation section 22 with the condensation section 26. The evaporation sections 226 of the two heat pipes 20 are received in the parallel grooves 16 of the base 10 and fixed in place by soldering, and the condensation sections 26 of the heat pipes 20 extend away from and substantially perpendicular to the base 10. The condensation sections 26 of the two heat pipes 20 are parallel to each other and evenly spaced.

The heat dissipation member 30 comprises a cylindrical heat transfer wall 32 constructed around an axis substantially perpendicular to the base 10. A through opening 36 is defined by the heat transfer wall 32, which extends along the axis and surrounded by the heat transfer wall 32. The heat transfer wall 32 has a first open end 321 adjacent to but spaced from the base 10, and a second open end 322 opposite to the first open end 321 and away from the base 10. The through opening 36 communicates with the outside of the heat transfer wall 32 via the open ends 321, 322. A plurality of fins 34 protrude from an inner face of the heat transfer wall 32 and extend from the first open end 321 to the second open end 322. The fins 34 are separated from each other at a uniform distance and extend in planes passing through the axis. A plurality of air channels (not labeled) are defined between the fins 34, which extend parallel to the axis and communicate with the outside of the heat transfer wall 32 via the open ends 321, 322. The fins 34 extend towards the axis and the tips of the fins 34 are spaced from the axis so that a chamber is defined within the opening 36, surrounded by the tips of the fins 34. Each of the fins 34 tapers from the root on the heat transfer wall 32 towards the tip thereof. The heat dissipation member 30 and the heat pipes 20 are thermally coupled by the connection of the condensation sections 26 with the heat transfer wall 32 by soldering.

During assembly, the heat pipes 20 and the heat dissipation member 30 can be connected together in many ways. Referring to FIG. 2 again, the heat dissipation member 30 is divided into four identical heat dissipation sub-members 300. Each heat dissipation sub-member 300 includes a quarter of the heat transfer wall 32, referred to hereafter as a heat transfer sub-wall 320, and some fins 340, a quarter of the whole number of the fins 34, extending from the heat transfer sub-wall 320. The heat transfer sub-walls 320 each define two grooves 302 at interfaces of adjacent two heat transfer sub-walls 320. Two adjacent grooves 302 form a channel for receiving the condensation section 26 of the heat pipe 20 when two adjacent heat dissipation sub-members 300 are combined together. The heat dissipation sub-members 300 are combined into the unitary heat dissipation member 30 and sandwich the heat pipes 20 therebetween, a close contact between the heat transfer sub-wall 320 and the heat pipe 20 may be established by soldering. Each condensation section 26 of the heat pipe 20 is sandwiched between two heat transfer sub-walls 320 of adjacent heat dissipation sub-members 300.

The fan 40 has an annular bracket 42 and an impeller 44 mounted in the bracket 42. The fan 40 is mounted to the second open end 322 of the heat transfer wall 32 to provide airflow entering the opening 36 and passing through the channels between the fins 34, and thus helping to carry away heat from the fins 34.

When the heat dissipation device with heat pipe is applied to an electronic component, the base 10 contacts the electronic component to absorb heat therefrom and conducts it to the heat pipes 20. The heat is transferred along the heat pipes 20, from the evaporation sections 22 to the condensation sections 26, to the heat transfer wall 32, and then to the fins 34 for dissipation assisted by the fan 40.

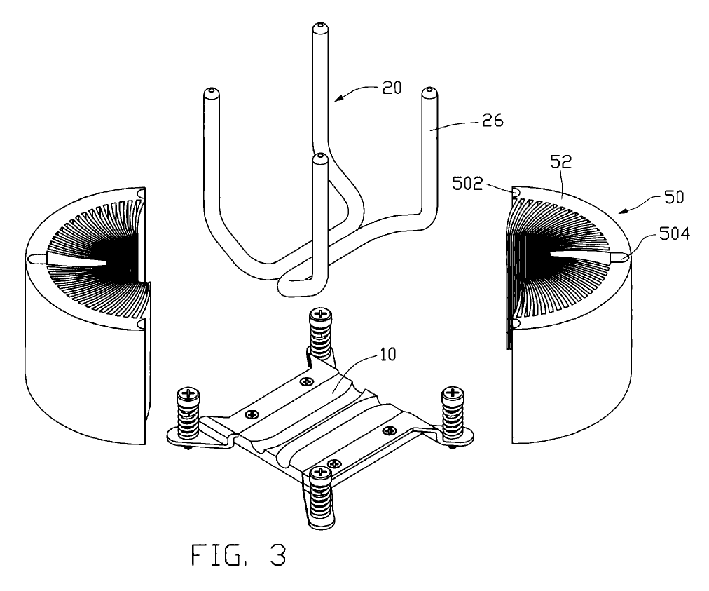

FIG. 3 illustrates a second embodiment of the present invention. In this practice, a base 10 and two heat pipes 20 identical to that of the first embodiment, and a heat dissipation member (not labeled) similar to that of the first embodiment, are provided. The heat dissipation member is divided into two identical heat dissipation sub-members 50. Each heat dissipation sub-member 50 defines a groove 504 in the inner face of the heat transfer wall 52 thereof, replacing two of the four channels of the first embodiment, and two channels 502 identical to that of the first embodiment are duplicated. The heat dissipation member is divided where the two channels 502 pass. The grooves 504 are exposed to a central opening (not labeled), defined by the heat dissipation sub-members 50 when combined together, and alternated with the channels 502 along the inner circumference of the heat transfer wall 52. One condensation section 26 of each heat pipe 20 is received in one of the grooves 504, and the other received in the channels 502 of the same heat dissipation sub-member 50 and sandwiched between the heat dissipation sub-member 50 and an adjacent one. The remaining structure and arrangement thereof are correspondingly duplicated from the first embodiment.

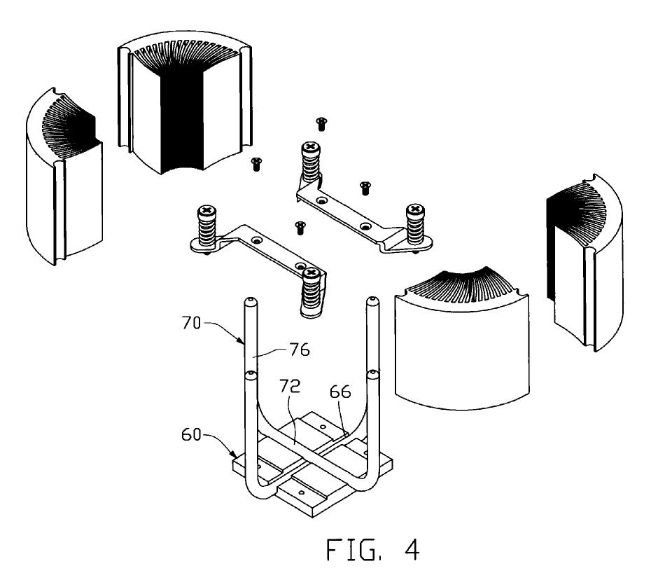

FIG. 4 illustrates a third embodiment of the present invention. In this practice, a base 60 defines two orthogonal grooves 66 on a top face thereof. Two U-shaped heat pipes 70 are so arranged that two evaporation sections 72 thereof are respectively received in the corresponding grooves 66, perpendicular to each other, and the condensation sections 76 thereof extending away from the base 60, parallel to each other. The remaining structure and arrangement thereof are correspondingly duplicated from the first embodiment.

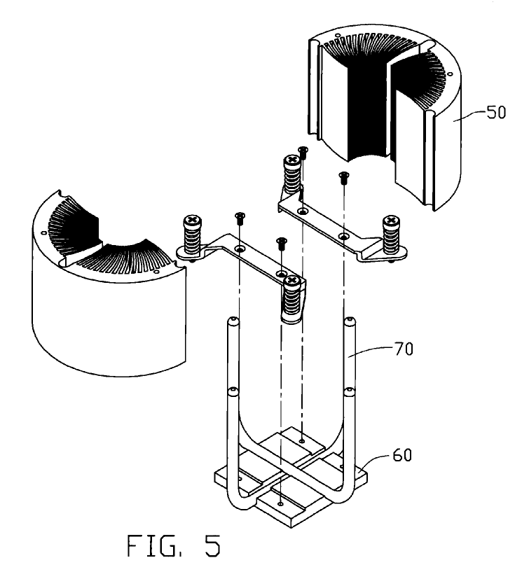

FIG. 5 illustrates a forth embodiment of the present invention. In this arrangement, the heat dissipation member is constructed, divided and combined in the same manner as that of the second embodiment; the base is identical to that of the third embodiment; and the heat pipe are arranged in the same manner as that of the third embodiment.

From the above description, it is apparent the heat dissipation member can be easily changed to other similarly arranged structures. For example, the heat transfer wall 32, 52 can be formed to a hollow polygonal tube having three, five or more sides, with a through opening defined therein; the channels can be all replaced by grooves 504 on the inner face of heat transfer wall 32, 52; and the fins 340 can be fabricated separately from the heat transfer wall 320, 520 and then mounted thereto.

Additionally, some fins can also be applied to an outer face of the heat transfer wall 32, 52 for strengthening heat dissipation of the heat dissipation member 30, 50.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat pipe type heat dissipation device comprising:
at least a heat pipe connected to the base; and
a heat dissipation member connected to the at least a heat pipe, including a heat transfer wall constructed around and separated from an axis of the heat dissipation member so as to define a through opening in which a plurality of fins extend from an inner face of the heat transferring wall toward the axis, thereby defining a plurality of air channels between the fins in the opening.

2. The heat dissipation device as described in claim 1, wherein the base has a bottom face for contacting with an electronic component, and the axis is substantially perpendicular to the bottom face.

3. The heat dissipation device as described in claim 1, wherein the heat transfer wall has a first open end adjacent to but spaced from the base, and a second open end opposite to the first open end and away from the base.

4. The heat dissipation device as described in claim 3, wherein each of the fins extends from the first open end towards the second open end along a line parallel to the axis.

5. The heat dissipation device as described in claim 1, wherein the fins each have a tip adjacent to but spaced from the axis, therefore defining chamber surrounded by the tips within which the axis is contained.

6. The heat dissipation device as described in claim 5, wherein the fins taper from roots thereof to the tips.

7. The heat dissipation device as described in claim 3, wherein a fan is mounted to the second open end of the heat transfer wall to provide airflow for passing through the channels between the fins.

8. The heat dissipation device as described in claim 1, wherein the heat transfer wall has a cylindrical configuration.

9. The heat dissipation device as described in claim 1, wherein the heat dissipation member is formed by combining four heat dissipation sub-members together, which each have a part of the heat transfer wall and some of the fins.

10. The heat dissipation device as described in claim 9, wherein a heat transfer sub-wall of each of the heat dissipation sub-members defines a groove for partly receiving the at least a heat pipe.

11. The heat dissipation device as described in claim 1, wherein the heat dissipation member is formed by combining two heat dissipation sub-members together, which each include a part of the heat transfer wall and some of the fins.

12. The heat dissipation device as described in claim 11, wherein a heat transfer sub-wall of each of the heat dissipation sub-members defines grooves for partly receiving the at least a heat pipe.

13. The heat dissipation device as described in claim 1, wherein the at least a heat pipe is in the form of U-shape, including an evaporation section situated on the base and two condensation sections bent from opposite ends of the evaporation section connected to the heat transfer wall of the heat dissipation member.

14. The heat dissipation device as described in claim 13, wherein the at least a heat pipe comprises two heat pipes with two evaporation sections thereof being perpendicular to each other and condensation sections thereof being parallel to each other.

15. The heat dissipation device as described in claim 13, wherein the at least a heat pipe comprises two heat pipes with two evaporation sections thereof being parallel to each other and condensation sections thereof being also parallel to each other.

16. The heat dissipation device as described in claim 14, wherein the condensation sections are evenly spaced from each other.

17. The heat dissipation device as described in claim 13, wherein the condensation sections extend parallel to the axis.

18. A heat dissipation device comprising:
a base adapted for contacting with a heat-generating electronic component;
a cylinder-like heat dissipation member mounted on the base, consisting of a plurality of heat dissipation sub-members combined together, having an outer wall and a plurality of fins extending from the outer wall toward a central axis of the heat dissipation member, wherein each of the heat dissipation sub-members has a groove extending parallel to the central axis; and
at least a heat pipe having an evaporation section thermally connecting with the base and a condensation section thermally received in the grooves of the heat dissipation sub-members.

19. The heat dissipation device as described in claim 18, wherein the at least a heat pipe comprises two heat pipes with evaporation sections thereof being thermally connected with the base and orthogonal to each other and condensation sections thereof being parallel to each other.

20. The heat dissipation device as described in claim 18, wherein the at least a heat pipe comprises two heat pipes with evaporation sections thereof being thermally connected with the base and parallel to each other and condensation sections thereof being also parallel to each other.
